(19) United States
(12) Patent Application Publication
(10) Pub. No.: US 2025/0238201 A1
(43) Pub. Date: Jul. 24, 2025

(54) Binary Adders of Low Transistor Count

(71) Applicant: NEOLOGIC LTD., Tel-Mond (IL)

(72) Inventors: Avi MESSICA, Tel-Mond (IL); Ziv LESHEM, Pardesia (IL)

(21) Appl. No.: 18/844,748

(22) PCT Filed: Mar. 6, 2023
(86) PCT No.: PCT/IL2023/050228

§ 371 Date: Sep. 6, 2024

Related U.S. Application Data
(60) Provisional application No. 63/317,545, filed on Mar. 8, 2022.

(51) Int. Cl. G06F 7/50; H03K 19/21

(52) U.S. Cl. CPC G06F 7/50; H03K 19/21

(57) ABSTRACT

A method for implementing a logic circuit employing a combination of binary adders of different lengths having summation and carry outputs and AND gates, comprising the steps of replacing at least one known CMOS implemented binary adder with an improved binary adder consisting of a logic block for performing summation between binary inputs of the logic block; a restoration block, connected between the output of the logic block and the output of the binary adder circuit, for compensating for voltage level losses when the output is in a high logic state or low logic state. The at least one CMOS AND gate is replaced with a high Fan-in AND gate being above a predetermined threshold, by an improved AND gate consisting of a logic block for performing an AND operation between binary inputs of the logic block; a restoration block, connected between the output of the logic block and the output of the AND gate, for compensating for voltage level losses when the output being in a high logic state or low logic state.

### FIELD OF THE INVENTION

The present invention relates to the field of static logic digital circuits. More particularly, the invention relates to the efficient design of binary adders, which allows reducing the number of required transistors, the semiconductor area, and the power consumption.

### BACKGROUND OF THE INVENTION

Binary adders are the main components used in VLSI circuits for arithmetic operations, multiplexing, and digital filters. The circuit performance of a multi-bit adder depends on the design of a basic adder, as well as on the topology of the plurality of basic adders that form the multi-bit adder; i.e. cascaded stages, tree structure, etc.

CMOS gates are superior to single-type MOSFETs with respect to power dissipation but inferior in packing density and speed. CMOS gates are also limited to a relatively small fan-in (the number of inputs a gate can handle—in most cases up to four inputs) and hence, higher functions than simple logic (e.g. arithmetic operations) require cascading multiple stages of CMOS gates that increase the semiconductor area, as well as power dissipation and latency. Furthermore, advanced CMOS technology nodes (i.e. from 65 nm down to 3 nm) suffer from high static power dissipation (due to subthreshold as well as junction leakage). Since CMOS adders are complex and consume a relatively large semiconductor area, other alternatives have been sought via alternative topologies or other types of logic.

A comprehensive study of one-bit full adders was carried out by Mehedi et al. (Comprehensive study of 1-Bit full adder cells: review, performance comparison, and scalability analysis, Mehedi Hasan, Abdul Hasib Siddique, Abdal Hoque Mondol, Mainul Hossain, Hasan U. Zaman & Sharnali Islam. SN Applied Sciences volume 3, Article number: 644, 2021) where they discussed the pros and cons of single-transistor logic adders such as Complementary Pass Logic (CPL) for which voltage swing degradation is a key concern, or a Transmission-gate (TG) based adder in which the issue of voltage swing degradation is solved but poor drive power is a major issue. US U.S. Pat. No. 4,559,609 describes such TG adder. Hybrid-logic based full adder circuits that attempt to solve the voltage swing degradation suffer either from an increased area, higher transistor count, or both. Recent Gate Diffusion Input (GDI) adders such as those described by Arkadiy Morgenshtein et al. (Arkadiy Morgenshtein et al., Full-Swing Gate Diffusion Input logic—Case-study of low-power CLA adder design, Integration—the VLSI journal Vol 47, pp. 62-70, 2014) suffer from voltage degradation and reduced drive capability as well. Mehedi et al. analyzed other implementations of adders that all suffer from one or more of the above-mentioned drawbacks. In general, pass-transistor based adders such as those described in U.S. Pat. No. 4,905,180 are at disadvantage to CMOS adders because NMOS transistors are weak conductors of logic “1” and PMOS transistors are weak conductors of logic “0”. Transmitting a logic “1” through NMOS transistor results in compromised signal integrity due to voltage drop (Vdd−Vtn instead of Vdd) at the output. Similarly transmitting logic “0” through a PMOS transistor results in |Vtp| at the output instead of zero voltage (i.e., ground).

The most basic CMOS one-bit half adder (1bHA) is comprised of a two-input XOR gate for calculating the sum and a two-input AND gate for calculating the carry-out of the addition operation of two 1-bit numbers. U.S. Pat. No. 4,054,788 patent describes, for example, one of many implementations of a 1bHA that improves latency at the expense of increased transistor count (w.r.t CMOS) as well as increased complexity (i.e. resistors). It is challenging to devise a 1bHA circuit that outperforms CMOS for all performance metrics (i.e. area, power, and latency).

The most compact CMOS one-bit full adder (1bFA) comprises 28 transistors. As discussed by Mehedi et al., alternatives that comprise fewer transistors are inferior either in signal integrity, driving power, semiconductor area, or combinations thereof.

Apart from one-bit adders, four-bit adders are most commonly used for the design of multi-bit adders (i.e. 8-bit, 16-bit, 32-bit, and 64-bit). Four-bit adder circuits either exhibit a regular, repeating, structure by chaining or cascading one-bit adders or trade improved speed for increased area and complexity (non-regular structure). The literature is abundant with different architectures of four-bit adders. A Carry Ripple Adder (CRA) is described in U.S. Pat. Nos. 4,439,835 and 6,978,290B2 by concatenating four 1bFA in series. It is the most basic of four-bit adders and has a simple and regular structure. However, CRA is slow for multi-bit addition of binary numbers (e.g. 16 bit). It is characterized by O(n) area and latency (where n is the number of bits of an addendum). U.S. Pat. Nos. 3,100,835, 5,027,312, and 5,396,445 described a Carry-Select-Adder (CSelA) that improves upon CRA's latency. It consists of two paralleling ripple-carry adders and a multiplexer. CSelA has O(n) area and O(\sqrt{n}) latency and so are the Carry-Skip-Adder described in U.S. Pat. No. 6,199,091B1 and the Carry-Increment-Adder described in U.S. Pat. No. 5,548,546. U.S. Pat. No. 7,111,033B2 presented a Carry-Save-Adder (CSA) that features O(n) area and improved O(log(n)) latency. U.S. Pat. No. 5,964,827 described a fast Carry Look-Ahead Adder (CLA) that is characterized by an increased area of O(n log(n)) in return for lower O(log(n)) latency. However, it suffers from an irregular structure that complicates its layout due to wiring congestions. Noteworthy, CLA adders can be realized in just two gate stages if there is no limit on a fan-in/out. CLA belongs to a family of parallel prefix adders (PPA) of which Kogge-Stone adder (described in Kogge, Peter Michael and Stone, Harold S. A Parallel Algorithm for the Efficient Solution of a General Class of Recurrence Equations. IEEE Transactions on Computers. C-22 (8): 786-793, 1973) and Brent-Kung adder belong (described in Brent, Richard Peirce and Kung, Hsiang Te. A Regular Layout for Parallel Adders. IEEE Transactions on Computers. C-31 (3): 260-264, 1982) and are commonly used despite their increased area and layout shortcomings. U.S. Pat. No. 5,504,915 described a Wallace-Tree Adder (WTA) of a multiple-stage adder. However, tree structure adders are relatively slow and less common as well as more exotic adders such as neural networks adder (described in U.S. Pat. No. 5,016,211) and the like.

It is therefore an object of the present invention to provide a one-bit and four-bit adder circuits implementation, which reduces the required number of transistors, compared to a similar implementation using known CMOS technology.

It is another object of the present invention to provide a one-bit and four-bit adder circuits implementation, which reduces power dissipation.

It is another object of the present invention to provide any multi-bit adder implementation, which saves semiconductor area, reduces the latency and the power dissipation.

Other objects and advantages of the invention will become apparent as the description proceeds.

### SUMMARY OF THE INVENTION

A 1-bit binary adder with a reduced number of transistors and semiconductor area having summation and carry outputs, comprising:
a) a logic block for performing summation between binary inputs of the logic block; and
b) a restoration block, connected between the output of the logic block and the output of the binary adder circuit, for compensating for voltage level losses when the output is in a high logic state or low logic state.

A multi-bit adder, implemented by a combination of the 1-bit binary adder described above.

The voltage at the summation and carry outputs may be compatible with a “1” logic level or with a “0” logic level.

In one aspect, the number of transistors required for implementing the binary adder is smaller than 28.

The binary adder according to claim 1, may be implemented as a Full Adder (FA) or as a Half Adder (HA) or a combination thereof.

The restoration block may consist of:
a standard CMOS inverter;
a standard CMOS buffer;
a Schmitt trigger;
a combination thereof.

A method for implementing a logic circuit employing a combination of binary adders of different lengths having summation and carry outputs and AND gates, comprising the steps of:
a) replacing at least one known CMOS implemented binary adder with an improved binary adder consisting of:
   a.1) a logic block for performing summation between binary inputs of the logic block;
   a.2) a restoration block, connected between the output of the logic block and the output of the binary adder circuit, for compensating for voltage level losses when the output is in a high logic state or low logic state;
b) replacing at least one CMOS AND gate with a high Fan-in AND gate being above a predetermined threshold, by an improved AND gate consisting of:
   b.1) a logic block for performing an AND operation between binary inputs of the logic block; and
   b.2) a restoration block, connected between the output of the logic block and the output of the AND gate, for compensating for voltage level losses when the output being in a high logic state or low logic state.

A method for implementing a logic circuit employing a combination of binary adders of different lengths having summation and carry outputs and AND gates, comprising the steps of:
a) replacing at least one known CMOS-implemented binary adder with an improved binary adder consisting of:
   a.1) a logic block for performing summation between binary inputs of the logic block;
   a.2) a restoration block, connected between the output of the logic block and the output of the binary adder circuit, for compensating for voltage level losses when the output is in a high logic state or low logic state;
   a.3) replacing at least one CMOS AND gate with a high Fan-in AND gate being above a predetermined threshold, with an improved AND gate consisting of:
   b.1) a logic block for performing an AND operation between binary inputs of the logic block; and
   b.2) a restoration block, connected between the output of the logic block and the output of the AND gate, for compensating for voltage level losses when the output is in a high logic state or low logic state.

The high Fan-in AND gate further comprises a pull-down block connected between the logic block and the output of the AND gate, for further discharging the voltage that corresponds to the high logic state to ground, following logic operations that entail a low logic state, in addition to discharging via the inherent current leakage path.

The pull-down block may be selected from the group of:
a diode.
transistor configured to operate as a diode;
a plurality of transistors configured to operate as a diode;
a combination of PMOS and NMOS transistors that acts as a diode.

The logic block of the high Fan-in AND gate may be a stack of connected transistors, implementing the AND gate, or a parallel connection of transistors implementing the AND gate, or a combination thereof.

The predetermined Fan-in threshold may be three.

A multi-bit adder, implemented by a combination of the 1-bit binary adder described above and at least one high Fan-in AND gate.

A multiple-bit binary adder with a reduced number of transistors and semiconductor area having summation and carry outputs, comprising a combination of two or more parallelly or serially connected 1-bit and/or 4-bit binary adders, wherein each 1-bit and/or 4-bit adder comprises:
a) a logic block for performing summation between binary inputs of said logic block; and
b) a restoration block, connected between the output of said logic block and the output of said binary adder circuit, for compensating for voltage level losses when said output is in a high logic state or low logic state.

The added numbers may contain an arbitrary number of bits and may be connected in a hierarchical architecture.

The binary adder may be used for performing subtraction operations, for example, using 2's complement.

Unless otherwise defined, all technical and/or scientific terms used herein have the same meaning as commonly understood by one of ordinary skill in the art to which the invention pertains. Although methods and materials similar or equivalent to those described herein can be used in the practice or testing of embodiments of the invention, exemplary methods and/or materials are described below. In case of conflict, the patent specification, including definitions will control. In addition, the materials, methods, and examples are illustrative only and are not intended to be necessarily limiting.

### BRIEF DESCRIPTION OF THE DRAWINGS

The above and other characteristics and advantages of the invention will be better understood through the following illustrative and non-limitative detailed description of preferred embodiments thereof, with reference to the appended drawings, wherein:

FIG. 1 is a circuit diagram of a one-bit half adder of the present invention using single transistors as logic elements, according to an embodiment of the invention consisting of 12 transistors;

FIG. 2 is another implementation of a one-bit half adder that combines single transistor logic and known CMOS logic consisting of 12 transistors;

FIG. 3 is a circuit diagram of the most compact known CMOS low voltage one-bit full-adder comprising 14 CMOS pairs, i.e. 28 transistors;

FIG. 4 is a circuit diagram of a hybrid one-bit full adder of the present invention, which comprises 18 transistors in combination with CMOS logic;

FIG. 5 is a circuit diagram of a one-bit full adder of the present invention, which comprises 22 transistors;

FIG. 6 is another circuit diagram implementation of a one-bit full adder of the present invention which comprises 16 transistors;

FIG. 7 is a block diagram of a three-input AND gate as described in international patent application No. PCT/IL2022/050981;

FIG. 8 (prior art) is a block diagram of a four-bit Carry-Ripple-Adder (CRA) architecture, comprising four one-bit full adders that are connected in series;

FIG. 9 (prior art) is a block diagram of a four-bit Carry-Save-Adder (CSA) architecture;

FIG. 10 (prior art) is a circuit diagram of a parallel prefix adder basic architecture known as Carry-Lookahead-Adder (CLA); and

FIG. 11 is a block diagram illustrating the implementation of a CLA with half adders and full adders of the present invention.

### DETAILED DESCRIPTION OF THE INVENTION

The present invention describes static 1-bit and 4-bit base adders of low transistor count that can be used to design any multi-bit adder to achieve area saving, power dissipation reduction, and lower latency. The one-bit adder circuits and four-bit adder circuits provided by the present invention use fewer transistors than the same circuits that are implemented using existing CMOS technology.

The present invention relates to digital circuits and in particular, to binary adders where it employs single-transistor-based logic, that is to say, circuits in which the addition function is achieved by non-CMOS logic. The methods of the present invention can be implemented to any adder architecture including, but not limited to, parallel prefix adders (PPAs—adders that use prefix operation in order to do efficient addition) such as Kogge-Stone adder, Brent-Kung adder (which are parallel prefix of the CSA adder form), tree adders such as Wallace tree adder, and others.

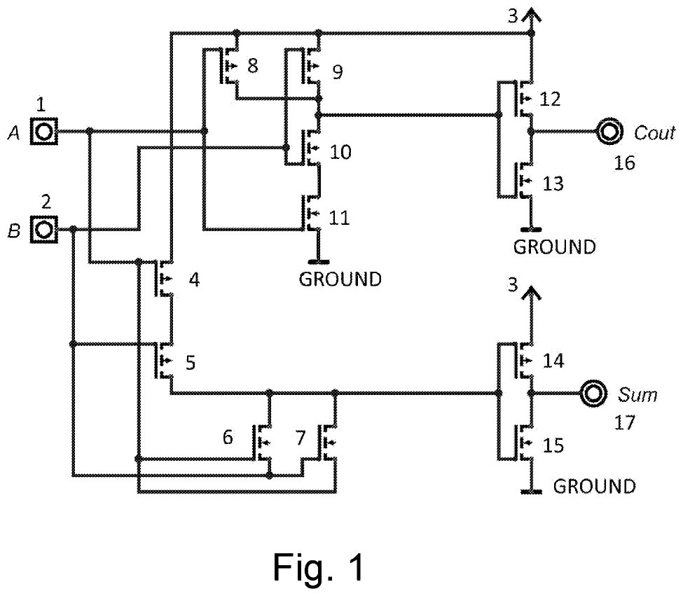

Pluralities of adders can be further combined in series or parallel to form addition, subtraction, multiplication, and division circuits. A preferred embodiment of the present invention and its advantages are better understood by referring to FIGS. 1-11, like numerals being utilized for like and corresponding parts.

A half adder with binary inputs A and B computes the sum output, as follows:

$$Sum = \overline{A} B + \overline{B} A = A ⊕ B \qquad ( Eq . 1 )$$

The bar in equation (1) denotes a complement value and the plus sign stands for a logical OR. Equation (1) is equivalent to an exclusive OR (XOR) between A and B, denoted by a symbol ⊕.

The carry-out of a half-adder is:

$${C}_{out} = AB \qquad ( Eq . 2 )$$

Equation (2) is equivalent to a logic AND operation of the binary numbers A and B.

With reference now to the drawings, and specifically to FIG. 1, the one-bit half-adder of FIG. 1 uses single-transistor logic.

A one-bit half-adder combines two one-bit binary numbers to form their sum and a carry where any carry from a preceding operation is ignored. Two one-bit inputs 1 and 2 are connected to a multiplicity of gates of single-type transistors that compute binary addition. A driving voltage 3 provides the supply voltage to the adder. According to the present invention, a one-bit half-adder novel implementation is provided comprising a first and a second block. The first block is comprised of a plurality of single-type transistors 4-11 to carry out the addition of two one-bit binary numbers (inputs 1, 2). The second block comprises transistors 12-15 and is adapted to restore the signals generated by the first block and output a sum (Sum) and carry-out (Cout) to acceptable voltage levels. In an embodiment of the half-adder, the threshold voltage and channel widths of transistors 4-5 may differ from those of transistors 6-7 or 8-9 as well as transistors 10-11. In another embodiment, the threshold voltage and channel widths of transistors 12, 13 or 14, 15 or may differ from those of transistors 4-11. In another embodiment of the adder depicted in FIG. 1 transistors 4, 5 have a higher threshold voltage, which is different from the threshold voltage of transistors 6,7. In another embodiment, transistors 8 and 9 are of different threshold voltage and channel widths of transistors 10-11 and similarly for transistors 4, 5 vs. transistors 6, 7. Using a plurality of threshold voltages as well as a plurality of channel widths allows tuning of the half-adder to output acceptable voltages and reduced power dissipation.

In an embodiment, the one-bit half-adder is implemented by connecting two one-bit inputs to a multiplicity of gates of single-type transistors that compute binary addition. Then, the sum is generated by a first block of the a one-bit half-adder, consisting of a first group of transistors. The Carry out is generated by a second block of the a one-bit half-adder, consisting of a second group of transistors.

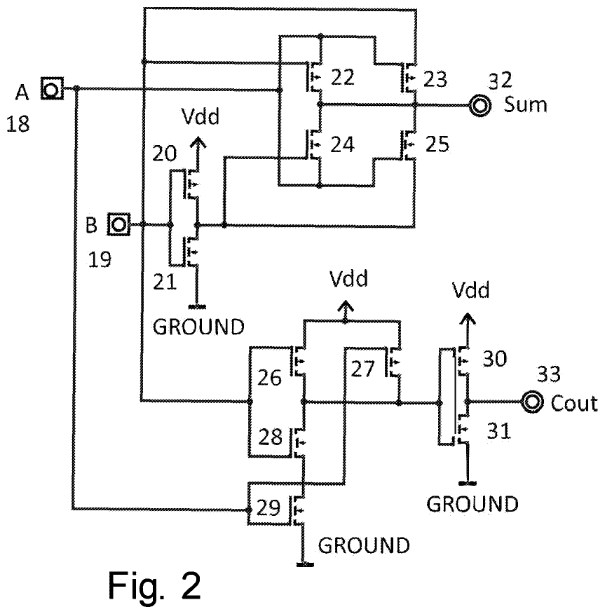

FIG. 2 presents another implementation of a half adder according to the present invention. Two one-bit inputs 18 and 19 are connected to a multiplicity of single-type transistors that compute binary addition. A driving voltage Vdd provides the supply voltage to the adder. According to the present invention, a one-bit half-adder novel implementation is provided comprising a first block comprised of transistors 20-25 for generating the sum 32 and a second block comprised of transistors 26-31 for generating the Carry out 33.

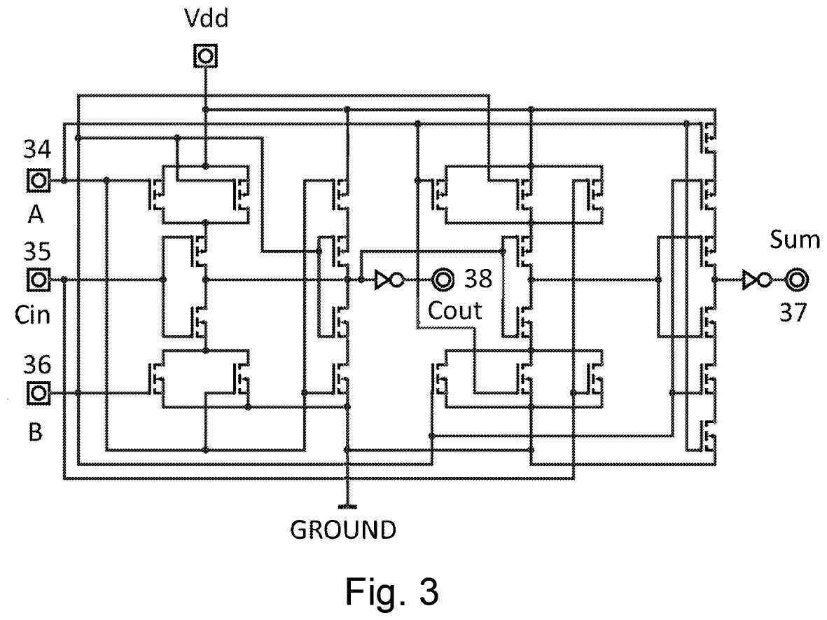

FIG. 3 presents an implementation of known CMOS most compact low voltage one-bit full adder comprising 28 transistors. The number of transistors required for implementing the binary adder may be smaller than 28. Two One-bit numbers 34, 36, and carry-in 35 are fed into the circuit to yield the sum 37, and carry-out 38 of the addendums (A+B|Carry-in=Sum|Carry-out). In FIG. 3, a one-bit full-adder is formed by cascading two one-bit half-adders. A driving voltage Vdd provides the supply voltage to the adder.

The one-bit binary numbers (A, B) 34 and 36 and carry-in (Cin) 35 from a preceding stage are added to form the sum 37 and carry-out 38 as given by:

$$Sum = ( A ⊕ B ) ⊕ {C}_{i n} \qquad ( Eq . 3 )$$

$${C}_{out} = A B + {C}_{i n} ( A ⊕ B ) \qquad ( Eq . 4 )$$

A different Boolean representation of Equations (3)-(4) is given as follows:

$$Sum = ( A ⊙ B ) ⊙ {C}_{i n} \qquad ( Eq . 5 )$$

$${C}_{out} = A ( A ⊙ B ) + {C}_{i n} \overline{( A ⊙ B )} \qquad ( Eq . 6 )$$

Where the symbol ⊙ stands for the exclusive NOR (XNOR) operator.

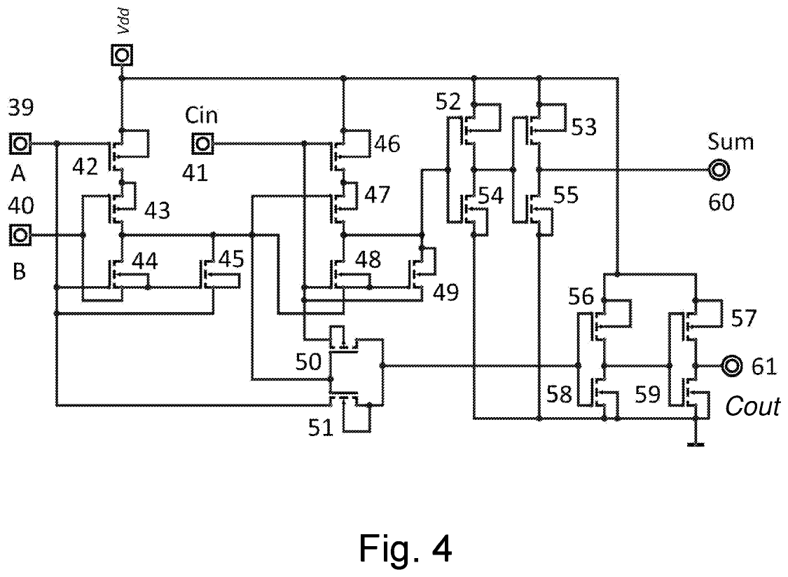

FIG. 4 illustrates a one-bit full-adder implementation that comprises 18 transistors, according to an embodiment of the present invention, based on equations (5)-(6), and comprises a first and a second block using single-transistor logic. Two one-bit binary numbers 39 and 40 are added including a carry-in 41 from a preceding stage. The first block is comprised of a plurality of single-type transistors 42-51 to compute the carry out the addition of two one-bit binary numbers. Transistors 42-45 perform an XNOR operation on inputs 39 and 40 (i.e. A⊙B) and their output is fed to transistors 46-49 for a consecutive XNOR operation with input 41 (carry-in) to result in the sum 60 of inputs 39 and 40 according to equation (5).

Transistors 50-51 act as a selector and output a carry-out based on inputs 39-41 (A, B, Carry-in). Whenever inputs 39, 40 are either (“0”, “0”) or (“1”, “1), selector 50, 51 outputs the input 39 as the carry-out; i.e. Cout=A and the Boolean operation A (A⊙B) is executed.

Whenever inputs 39, 40 are of odd “1” parity; that is either (“1”, “0”) and (“0”, “1”), then the output of the selector 50, 51 is the input carry; i.e. the Boolean operation Cᵢₙ(̅A̅⊙̅B̅)̅ is executed and Cout=Cin.

The sum and output carry are provided at outputs of a second block (restoration block), consisting of transistors 52-59, for compensating for voltage level losses when the output is in a high logic state or low logic state. The restoration block may consist of a standard CMOS inverter, a standard CMOS buffer, a Schmitt trigger or any combination thereof.

The second block is arranged to restore the sum and carry-out signals generated by the first block and output a sum and carry-out at acceptable voltage levels. In an embodiment of the full-adder, the threshold voltage and channel widths of transistors 42-49 may differ from those of transistors 50, 51 (implementing the selector) as well as transistors 52-59. In another embodiment of the adder depicted in FIG. 4, transistors 42, 43, or transistors 46, 47 have a threshold voltage that is different from the threshold voltage of transistors 44, 45 or 48, 49 or 50, 51. Using a plurality of threshold voltages as well as a plurality of channel widths, is made for tuning the full-adder to output acceptable voltages and reduce power dissipation. A driving voltage Vdd provides the supply voltage to the adder.

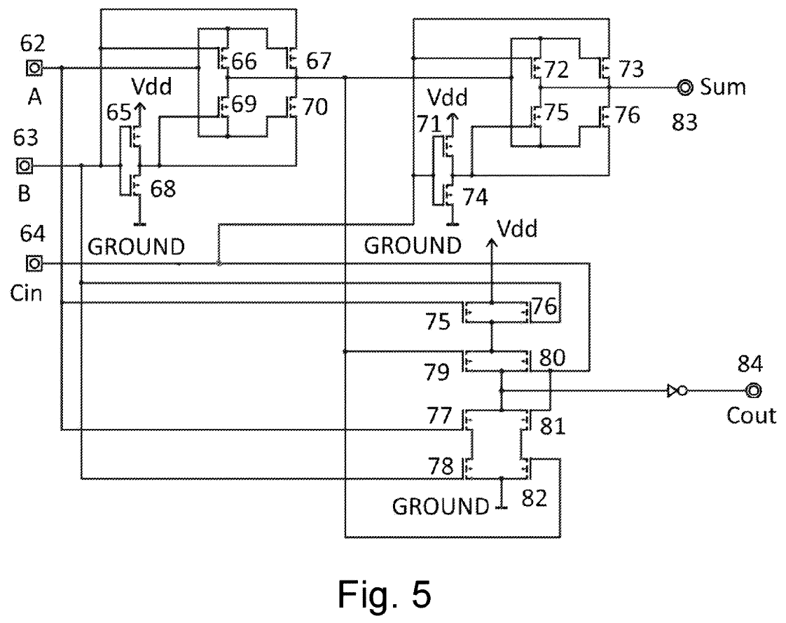

FIG. 5 is another implementation of a one-bit full-adder according to the present invention that comprises 22 transistors based on equations (3)-(4), and comprises a first and a second block using single-transistor logic. Two one-bit binary numbers A (62) and B (63) are added including a Carry-in 64 from a preceding stage. The first block is comprised of a plurality of single-type transistors to carry out the addition of two one-bit binary numbers. Transistors 65-70 perform an XOR operation on inputs and (i.e. A⊕B) and their output is fed to transistors 71-76 for a consecutive XOR operation with input carry-in to result in the sum 83 of inputs 62-64 according to equation (3).

Transistors 75-82 act as an AND-OR gate that determines the carry out result based on equation (4). Transistors 75-78 perform a logic AND function between inputs A 62 and B 63 and transistors 79-82 perform a logic AND function between carry-in 64 and A⊕B. The joint output of these two AND gates results in the AND-OR circuit that generates the carry out.

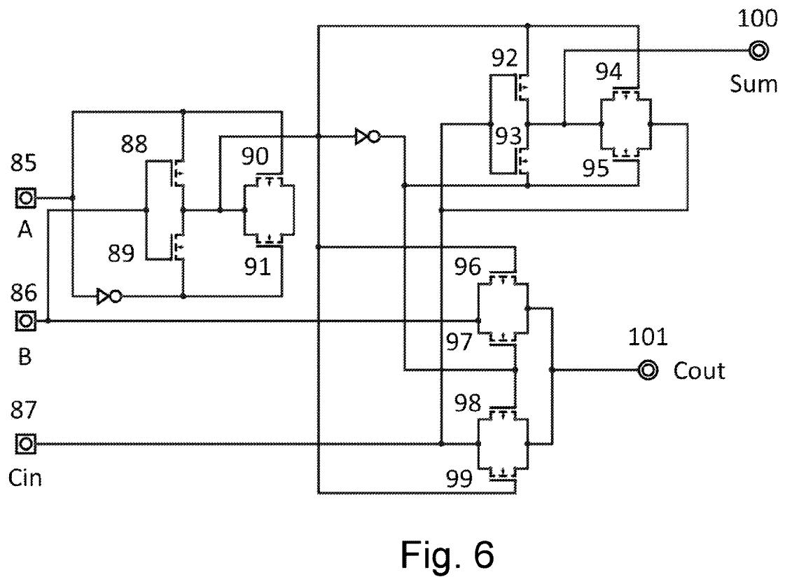

FIG. 6 is another implementation of a one-bit full-adder according to the present invention that comprises 16 transistors using transmission gates 90, 91 and 94, 95 and 96-99, and is based on equations (3)-(4). Two one-bit binary numbers A 85 and B 86 are added including a carry-in 87 from a preceding stage. Transistors 88-91 perform XOR operation between inputs A 85 and B 86 (i.e. A⊕B) and their output is fed to transistors 92-95 for a consecutive XOR operation with input (carry-in) to result in the sum of inputs 100 according to equation (3).

Transmission gate transistors 96-99 act as an AND-OR gate that determines the carry-out result based on equation (4). Transmission gate transistors 96-97 generate a logic AND function between inputs A and B and Transmission gate transistors 98-99 perform a logic AND function between Cin and A⊕B. The joint output of these two AND gates results in the AND-OR circuit that generates the carry out 101.

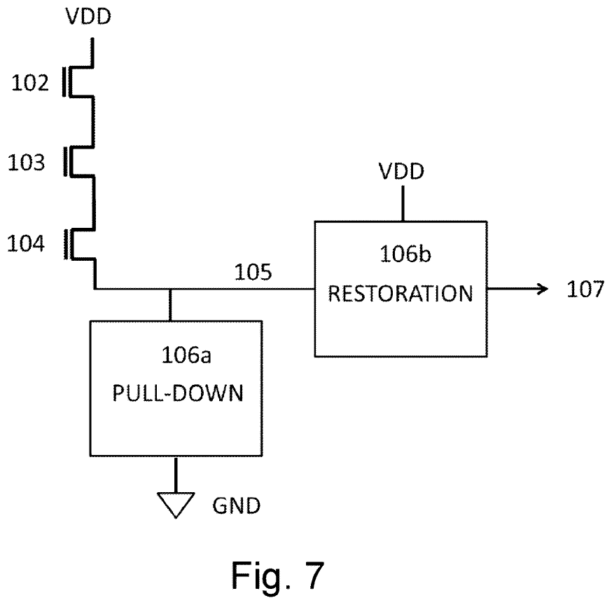

FIG. 7 is a block diagram of a three-input AND gate as described in international patent application No. PCT/IL2022/050981 (of the same applicant). An embodiment of the multi-input AND gate of FIG. 7 is used in some of the multi-bit full adders that are described in the present invention. In one embodiment of the circuit of FIG. 7, inputs 102-104 are fed into the gates of an n-type transistor stack that operates as a logic AND gate. When all the transistors are at “ON” state, the supply voltage Vdd is transferred to wire 105. Restoration block 106b compensates for a threshold voltage drop of the stack 102-104. Pull-down block 106a pulls the voltage on wire 105 to the ground when any of the inputs 102-104 is “0”.

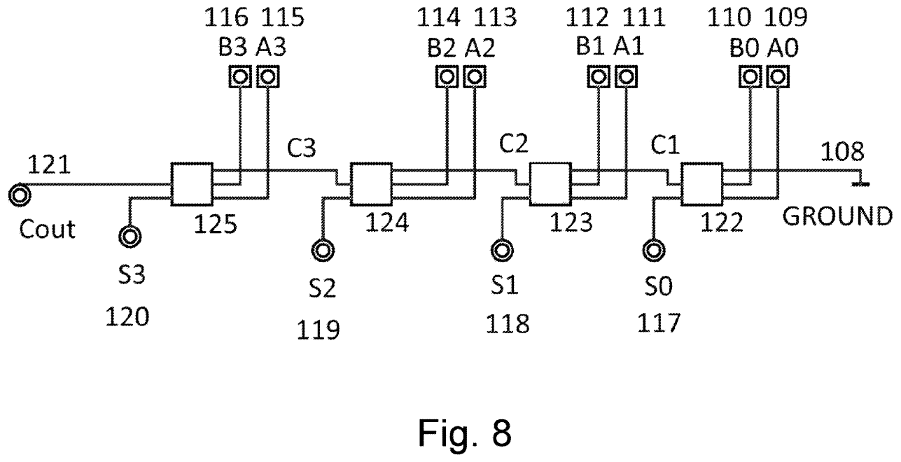

FIG. 8 is a generalized block diagram of a four-bit carry-ripple-adder (CRA architecture) as described in U.S. Pat. Nos. 4,439,835 and 6,978,290B2 comprising four one-bit full adders 122-125 in series. The carry input 108 of the first adder is ‘0” (i.e. ground) but can take “1” as well. The carry input of any other adder of the series is fed with a carry output of a preceding adder. Two four-bit numbers are added. The first addendum bits are 109, 111, 113, 115 (109 is LSB, 115 is MSB) and the second addendum bits are 110 (LSB), 112, 114, 116 (MSB). The summand bits are 117 (LSB), 118, 119, 120 (MSB), and carry out is 121. Prior art elements 122-125 comprise known CMOS one-bit full-adder of FIG. 3. In an embodiment of the present invention, a single or plurality, mix and match, placement of FIG. 3 known CMOS one-bit full-adder and one-bit full-adder of FIGS. 4-6 results in a CRA topology of fewer transistors, reduced latency, and reduced power dissipation. In another embodiment of the present invention, a CRA comprising all elements 122-125 of a full-adder of FIG. 4-6 results in fewer transistors, reduced latency, and reduced power dissipation.

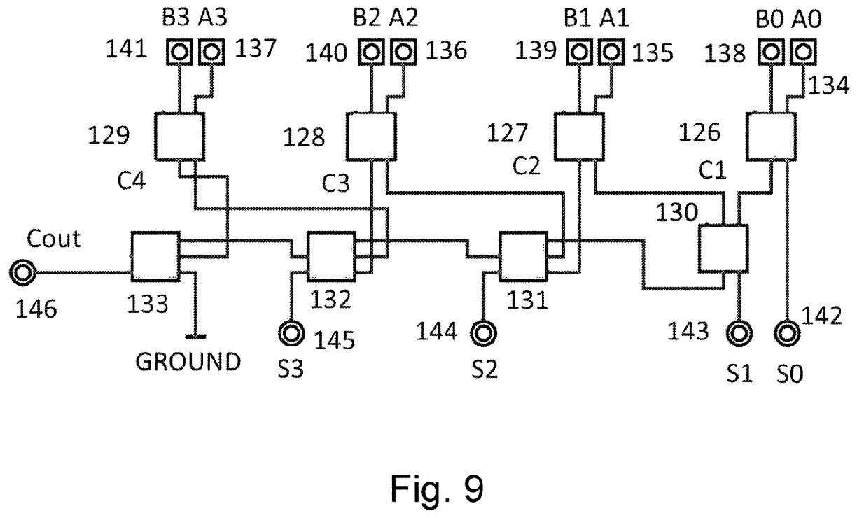

FIG. 9 (prior art) presents a four-bit Carry-Save-Adder (CSA) as described in U.S. Pat. No. 7,111,033B2. Two four-bit numbers are added. The first addendum bits are 134-137 (134 is LSB, 137 is MSB) and the second addendum bits are 138 (LSB), 139, 140, 141 (MSB). The summand bits are 142 (LSB), 143, 144, 145 (MSB), and carry-out is 146. Elements 126-130 comprise of known CMOS one-bit half-adder (i.e. the full adder of FIG. 3 with carry-in grounded) and elements 131-133 comprise of known CMOS one-bit full-adder of FIG. 3. In an embodiment of the present invention, a mix and match placement of single or plurality of the present invention's half and full adders, of FIG. 1-2 and FIG. 3-6 respectively, results in a CSA of fewer transistors, reduced latency, and reduced power dissipation. In another embodiment of the present invention a CSA comprising all elements 126-130 of the half adder of FIG. 1-2 and full adder of FIGS. 4-6 results in a CSA topology of fewer transistors, reduced latency, and reduced power dissipation.

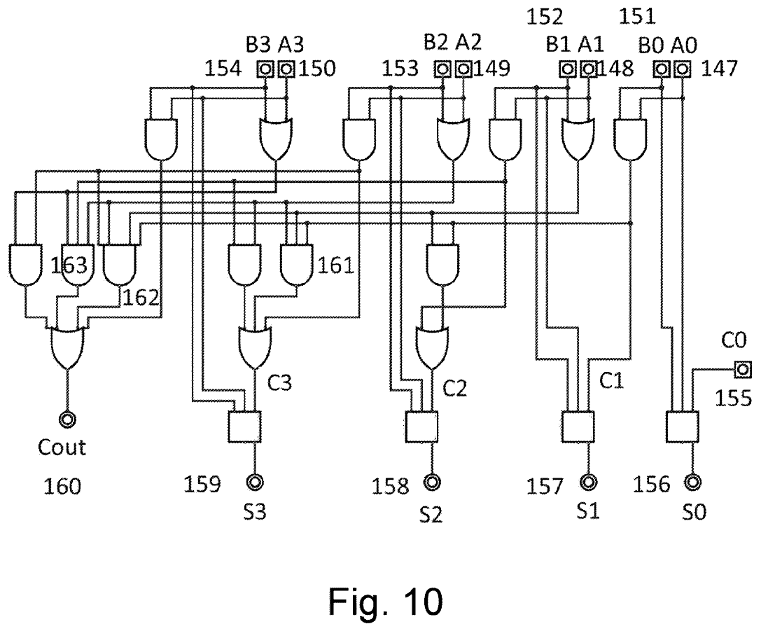

A basic parallel prefix adder of a four-bit Carry Lookahead Adder (CLA) as described in U.S. Pat. No. 5,964,827 is depicted in FIG. 10. The first addendum bits are 147-150 (147 is LSB, 150 is MSB) and the second addendum bits are 151 (LSB), 152, 153, 154 (MSB). The Carry-in bit is Co (155). The summand bits are 156 (LSB), 157, 158, 159 (MSB), and carry out is 160. Gates 161-163 are high Fan-in CMOS AND gates. In an embodiment of the present invention, a mix and match of a single or plurality of AND gates of FIG. 7 are dropped in as a replacement for known CMOS AND gates 161-163 to reduce the number of transistors and thereby save area, and shorten the adder's critical path as well as reduce power dissipation. As presented in international application PCT/IL2022/050981 (of the same applicant) AND gates of five, four, or three inputs can be constructed. In yet another embodiment of the present invention, all AND gates 161-163 are replaced with equivalent gates of the AND gate of FIG. 7 to further save area, shorten the adder's critical path as well as reduce power dissipation.

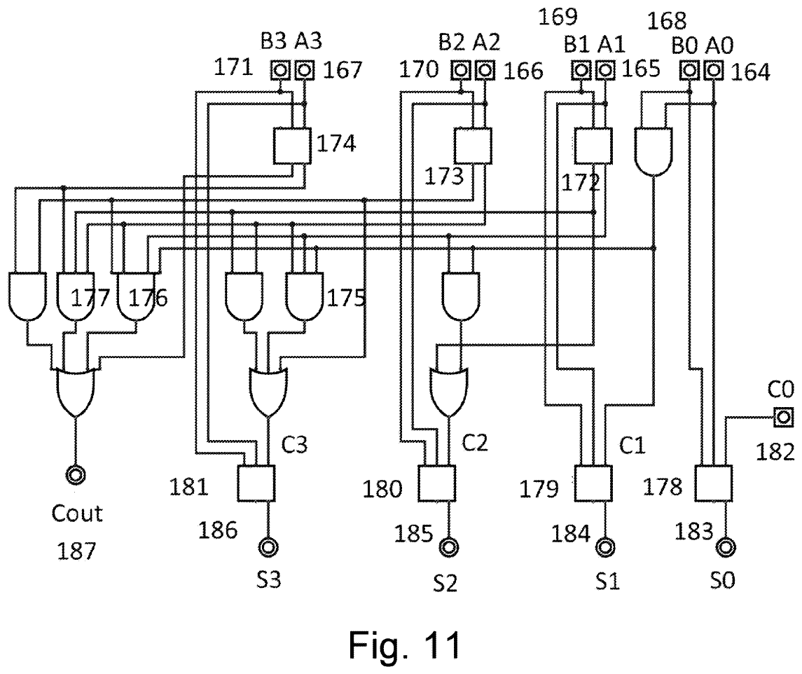

FIG. 11 presents a different block diagram of the same four-bit CLA of FIG. 10, using the half adder and full adder implemented according to the present invention. The input carry-in bit is 182. Two four-bit numbers A and B (A inputs 164-167 and B inputs 168-171) are summed. The summand bits are 183 (LSB), 184, 185, 186 (MSB), and carry-out is 187. Gates 175-177 are high Fan-in CMOS AND gates of 3 or more inputs. Prior art elements 172-174 are known CMOS one-bit half adders and 178-181 are known CMOS one-bit full-adders.

In an embodiment of the present invention, a mix and match of a single or plurality of the present invention's half adder of FIG. 1-2, full-adder of FIG. 3-6, and equivalent AND gates of FIG. 7 are mixed and matched with known CMOS circuits to reduce the transistor count; thereby saving area, shortening the adders' critical path as well as reducing power dissipation. In another embodiment of the present all half-adders 172-174, all high fan-in AND gates 175-177 as well as all full-adders 178-181 are replaced by the present invention half adder of FIG. 1-2, full-adder of FIG. 4-6, and equivalent AND gates of FIG. 7.

According to another embodiment, additions using a higher number of bits (such as 8 bit addition, 16 bit addition, 32 bit addition and the like) are performed by using any combination of 1 bit adders and/or of 4 bit adders to form adders with a higher number of bits, as well as adders which are connected in a hierarchical architecture (that is used to reduce the delay). In another embodiment, a concatenation of two, four or eighth 4-bit adders of FIGS. 8-11 can result in an 8-bit adder, a 16-bit adder, and a 32-bit adder, respectively. In another embodiment, a proper concatenation of the adders of FIG. 1-6 can form any adder of arbitrary size. In another embodiment, a concatenation of the adders of FIG. 1-6 with adders of FIG. 8-11 can form any adder of arbitrary size. In another embodiment adders of the present invention can be used in any multiple-bit adder architecture.

In one embodiment, the multiple-bit binary adder has summation and carry outputs, and comprises a combination of two or more parallelly or serially connected 1-bit and/or 4-bit binary adders. Each 1-bit and/or 4-bit adder comprises a logic block for performing summation between binary inputs of said logic block, and a restoration block, connected between the output of the logic block and the output of the binary adder circuit, for compensating for voltage level losses when the output is in a high logic state or low logic state.

Even though the above embodiments are related to addition operations, the present invention may be used for subtraction operations, as well, as will be appreciated by a person skilled in the art. For example, the subtraction of two binary numbers can be accomplished by adding 2's complement (2's complement is a mathematical operation to reversibly convert a positive binary number into a negative binary number with equivalent value, using the binary digit with the greatest place value to indicate whether the binary number is positive or negative. At the first step, the given decimal number is converted to binary. At the next step, one's complement of the binary number is taken by converting each ‘0’ to ‘1’ and ‘1’ to ‘0’. At the next step, ‘1’ is added to the one's complement. When the most significant bit is ‘1’, the number is signed as the negative of the subtrahend to the minuend and the final carry (if any) is disregarded. If the MSB bit in the result of addition is a ‘0’, then the result of addition is the correct answer. If the MSB bit is a ‘1’, this implies that the answer has a negative sign. The true magnitude, in this case, is given by the 2's complement of the result of the addition.

In one embodiment, a logic circuit employing a combination of binary adders having summation and carry outputs and AND gates is implemented by replacing at least one CMOS implemented binary adder with an improved binary adder that consists of a logic block for performing summation between binary inputs of the logic block; a restoration block, connected between the output of the logic block and the output of the binary adder circuit, for compensating for voltage level losses when the output being in a high logic state or low logic state; replacing at least one CMOS AND gate with a high Fan-in AND gate being above a predetermined threshold, by an improved AND gate consisting of a logic block for performing an AND operation between binary inputs of the logic block; a restoration block, connected between the output of the logic block and the output of the AND gate, for compensating for voltage level losses when the output being in a high logic state or low logic state.

In one embodiment, a logic circuit employing a combination of binary adders having summation and carry outputs and AND gates is implemented by replacing at least one CMOS implemented binary adder with an improved binary adder consisting of a logic block for performing summation between binary inputs of the logic block; a restoration block, connected between the output of the logic block and the output of the binary adder circuit, for compensating for voltage level losses when the output being in a high logic state or low logic state; replacing at least one CMOS AND gate with a high Fan-in AND gate being above a predetermined threshold, with an improved AND gate consisting of a logic block for performing an AND operation between binary inputs of the logic block; a restoration block, connected between the output of the logic block and the output of the AND gate, for compensating for voltage level losses when the output being in a high logic state or low logic state.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable sub-combination or as suitable in any other described embodiment of the invention. Certain features described in the context of various embodiments are not to be considered essential features of those embodiments unless the embodiment is inoperative without those elements.

Although the invention has been described in conjunction with specific embodiments thereof, it is evident that many alternatives, modifications, and variations will be apparent to those skilled in the art. Accordingly, it is intended to embrace all such alternatives, modifications, and variations that fall within the spirit and broad scope of the appended claims.

All publications, patents, and patent applications mentioned in this specification are herein incorporated in their entirety by reference into the specification, to the same extent as if each individual publication, patent, or patent application was specifically and individually indicated to be incorporated herein by reference. In addition, citation or identification of any reference in this application shall not be construed as an admission that such reference is available as prior art to the present invention. To the extent that section headings are used, they should not be construed as necessarily limiting.

1-23. (canceled)

24. A 1-bit binary adder with a reduced number of transistors and semiconductor area having summation and carry outputs, comprising:
a) a logic block for performing summation between binary inputs of said logic block; and
b) a restoration block, connected between the output of said logic block and the output of said binary adder circuit, for compensating for voltage degradation.

25. A multi-bit adder, implemented by a combination of several 1-bit binary adders of claim 24.

26. A binary adder according to claim 24, wherein the number of transistors required for implementing the binary adder is less than 28.

27. A binary adder according to claim 24, which is implemented as a Full Adder (FA) or as a Half Adder (HA).

28. A binary adder according to claim 24, in which the restoration block consists of:
a standard CMOS inverter;
a standard CMOS buffer;
a Schmitt trigger;
a combination thereof.

29. A multi-bit adder, implemented by a combination of the 1-bit binary adders of claim 24 and at least one high Fan-in AND gate, where said high Fan-in comprises five inputs or more.

30. A binary adder according to claim 24, in which a one-bit half-adder is implemented by:
a) connecting two one-bit inputs to a multiplicity of transistors that compute binary addition;
b) generating the sum by a first block of said one-bit half-adder, consisting of a first group of transistors; and
c) generating the Carry out by a second block of said one-bit half-adder, consisting of a second group of transistors.

31. A binary adder according to claim 24, in which the one-bit full-adder comprises a first block and a second block wherein:
two one-bit binary numbers are added including a Carry-in from a preceding stage;
said first block consists of a plurality of transistors to carry out the addition of two one-bit binary numbers;
performing a XOR or XNOR operation on the inputs;
performing a consecutive XOR or XNOR operation with a carry-in input, to obtain the sum of the inputs.

32. A multi-bit binary adder with a reduced number of transistors and semiconductor area having summation and carry outputs, comprising a combination of two or more, parallelly or serially connected n-bit binary adders wherein each n-bit adder comprises:
a) a logic block for performing summation between two arbitrary binary numbers inputs of said logic block; and
b) a second block consisting of a second group of transistors, for generating the Carry out; and
c) a restoration block, connected between the output of said logic block and the output of said binary adder circuit, for compensating for voltage level degradation.

33. A multi-bit binary adder according to claim 32, in which the n-bit binary adders are connected in a hierarchical architecture.

34. A 1-bit binary adder according to claim 32, used for performing subtraction operations, preferably, using 2's complement.

35. A method for implementing a logic circuit employing a combination of binary adders having summation and carry outputs and high Fan-in AND gates, comprising:
a) replacing at least one known CMOS binary adder with an improved binary adder consisting of:
a.1) a logic block for performing summation between binary inputs of said logic block;
a.2) a second block consisting of a second group of transistors, for generating the Carry out;
a.3) a restoration block, connected between the output of said logic block and the output of said binary adder circuit, for compensating for voltage degradation;
b) replacing at least one known CMOS AND gate with a high Fan-in AND gate of at least five inputs, consisting of:
b.1) a logic block for performing an AND operation between binary inputs of said logic block; and
b.2) a restoration block, connected between the output of said logic block and the output of said AND gate, for compensating for voltage degradation.

36. A method for implementing a multi-bit adder employing a combination of binary adders having summation and carry outputs with or without a high Fan-in AND gates, comprising:
a) replacing at least one known CMOS binary adder with an improved binary adder consisting of:
a.1) a logic block for performing summation between binary inputs of said logic block;
a.2) a second block consisting of a second group of transistors, for generating the Carry out;
a.3) a restoration block, connected between the output of said logic block and the output of said binary adder circuit, for compensating for voltage degradation;
a.4) replacing at least one known CMOS AND gate with a high Fan-in AND gate of at least five inputs consisting of:
b.1) a logic block for performing an AND operation between binary inputs of said logic block; and
b.2) a restoration block, connected between the output of said logic block and the output of said AND gate, for compensating for voltage degradation.

37. A method according to claim 35, wherein the high Fan-in AND gate further comprises a pull-down block connected between the pull-up logic block and the output of said AND gate, for further discharging the voltage that corresponds to the high logic state to ground, following logic operations that entail a low logic state, in addition to discharging via the inherent current leakage path.

38. A method according to claim 37, wherein the pull-down block of the high Fan-in AND gate is selected from the group of:
a diode.
transistor configured to operate as a diode;
a plurality of transistors configured to operate as a diode;
a combination of PMOS and NMOS transistors that acts as a diode.
a serial or parallel combination of stacks of transistors

39. A method according to claim 37, wherein the pull-up network logic block of the high Fan-in AND gate is a stack of serially connected transistors, implementing a pull-up network of the AND gate, or a parallel stacks of connected transistors implementing a pull-up network of said AND gate, or a combination or multiple combinations thereof.
